(19) United States
(12) Patent Application Publication
(10) Pub. No.: US 2013/0135919 A1
(43) Pub. Date: May 30, 2013

(54) SEMICONDUCTOR STORAGE DEVICE

(71) Applicant: Makoto HAMADA, San Jose, CA (US)

(72) Inventor: Makoto HAMADA, San Jose, CA (US)

(21) Appl. No.: 13/304,500

(22) Filed: Nov. 25, 2011

(51) Int. Cl. G11C 7/06; G11C 11/00

(52) U.S. Cl. 365/148; 365/207

(57) ABSTRACT

According to one embodiment, a semiconductor storage device includes a stripe, a sense amplifier, a global signal line, and a controller. Blocks are in the stripe. The blocks are formed in a first direction. Each of blocks is made a read unit of data and includes a memory cell capable of holding the data provided along a row and a column. The sense amplifier is provided just under each of the blocks, and reads the data. The global signal line is formed so as to penetrate through the stripe in the first direction, and transfers the data read from the block to the sense amplifier. The controller controls a value of a reference current applied to the sense amplifier according to positional relationship between each area in which the sense amplifier is arranged and the block, which is made a read target of the data, out of the blocks.

### FIELD

Embodiments described herein relate generally to a semiconductor storage device, which makes a reference current applied to a sense amplifier variable according to a position of a memory cell, which is made a read target, for example.

### BACKGROUND

At the time of reading of data, a distance to the sense amplifier changes according to a selected block.

That is to say, wiring resistance of a connected bit line is variable according to a position of the memory cell, which is made the read target.

Therefore, even when the memory cell holds the same data, voltage depression due to a length of the wiring resistance occurs and the data might be erroneously read.

### BRIEF DESCRIPTION OF THE DRAWINGS

FIG. 1 is a schematic diagram of a semiconductor storage device according to a first embodiment;

FIG. 2 is a schematic diagram illustrating a state in which data is read from the semiconductor storage device according to the first embodiment;

FIG. 3A is a planar view illustrating a bay according to the first embodiment;

FIG. 3B is a planar view of a peripheral circuit provided just under the bay according to the first embodiment;

FIG. 3C is an enlarged view of FIG. 3B;

FIG. 4 is a perspective view of a memory cell according to the first embodiment;

FIG. 5 is a circuit example of a memory cell array according to the first embodiment;

FIG. 6 is state distribution of the memory cell according to the first embodiment;

FIG. 7 is a schematic diagram illustrating connection of a block, a global signal line, and a sense amplifier according to the first embodiment;

FIG. 8 is a circuit example illustrating the connection of the block, the global signal line, and the sense amplifier according to the first embodiment;

FIG. 9 is a circuit diagram illustrating the connection of the block, the global signal line, and the sense amplifier according to the first embodiment;

FIG. 10 is a schematic diagram of the block according to the first embodiment and a reference current generating circuit, which generates a reference current variable according to an arranging position of the block; and

FIG. 11 is a schematic diagram of the block according to the first embodiment and the reference current variable according to the arranging position of the block.

### DETAILED DESCRIPTION

Hereinafter, embodiments will be described with reference to the drawings. In this description, common reference numerals are assigned to common parts throughout the drawings.

In general, according to one embodiment, a semiconductor storage device includes a stripe, a sense amplifier, a global signal line, and a controller. In the stripe, a plurality of blocks, each of which is made a read unit of data and includes memory cells capable of holding the data provided along a row and a column, are formed in a second direction. The sense amplifier is provided just under each of the blocks to read the data. The global signal line is formed so as to penetrate through the stripe in the second direction to transfer the data read from the block to the sense amplifier. The controller controls a value of a reference current applied to each of the sense amplifiers according to positional relationship between each area in which the sense amplifier is arranged and the block, which is made a read target of the data, out of a plurality of blocks.

### One Embodiment

In this embodiment, a case in which a resistance random access memory (ReRAM) is used as a memory cell is described as an example. The ReRAM holds data “0” or “1” according to a level of a resistance value. At the time of reading of the data of the memory cell, the resistance value obtained by adding resistance of the memory cell and parasitic resistance of wiring is read; as a distance (wiring length) between the memory cell, which is made a read target, and a sense amplifier, which reads the data of the memory cell, becomes longer, the parasitic resistance of the wiring becomes larger according to this. This causes erroneous reading of the data. In consideration of this, in a semiconductor storage device according to this embodiment, a reference current, which flows through the sense amplifier, is variable according to a position on which the memory cell, which is made the read target, is arranged. According to this, the erroneous reading of the data due to the position on which the memory cell is arranged is prevented.

### 1. Entire Configuration Example

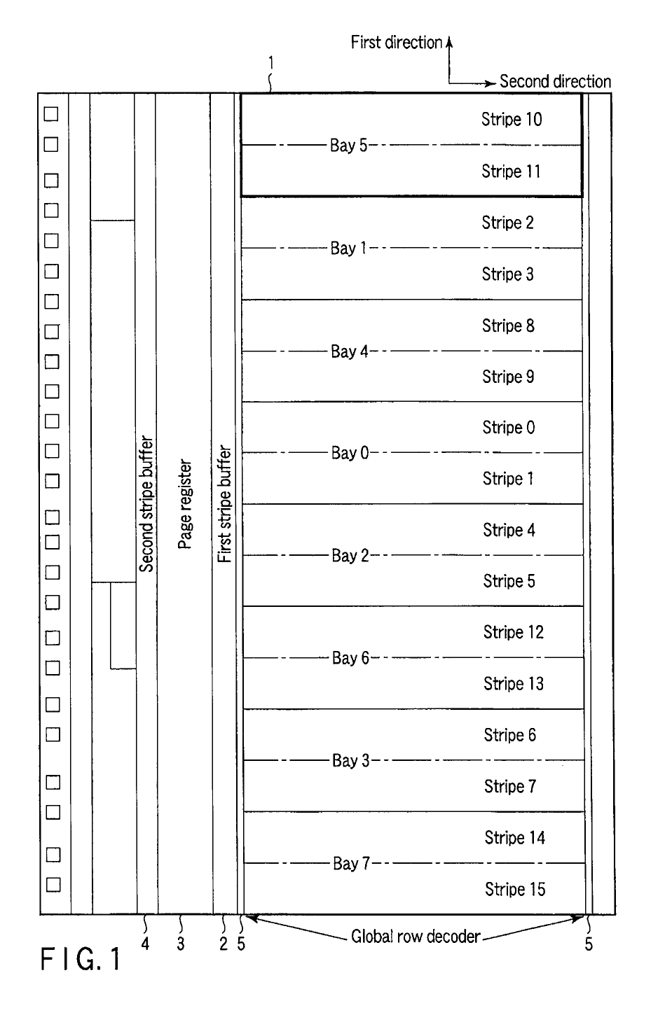

FIG. 1, which is a planar view of the semiconductor storage device according to this embodiment, is a schematic diagram illustrating an entire chip. As illustrated in FIG. 1, the semiconductor storage device is provided with a memory cell array 1, a first stripe buffer SB2, a page resister PR3, a second stripe buffer SB4, and a global row decoder GRD5 (not illustrated), for example.

### <Memory Cell Array 1>

The memory cell array 1 is provided with a plurality of bays B (for example, bays B0 to B7). Each of the bays B0 to B7 is formed of two stripes. For example, stripes STP0 and STP1 are provided in the bay B0, stripes STP2 and STP3 are formed in the bay B1, and similarly, stripes STP14 and STP15 are formed in the bay B7. Meanwhile, when the bays B0 to B7 are not distinguished from one another, they are simply referred to as the bays B, and similarly, when the stripes STP0 to STP15 are not distinguished from one another, they are simply referred to as the stripes STP.

The stripe STP is formed of a plurality of (for example, 32) blocks BLK and a plurality of memory cells MC are formed in each block BLK. The memory cells MC are provided on intersections of a plurality of bit lines BL provided in a first direction and a plurality of word lines WL provided in a second direction orthogonal to the first direction. In the block BLK, 64 bit lines BL, for example, and 128 word lines WL, for example, are formed. Meanwhile, the memory cell MC will be described later in detail.

### <First Stripe Buffer SB2>

The first stripe buffer SB2 is provided so as to correspond to the above-described stripe STP. The first stripe buffer SB2 temporarily holds the data read from the stripe STP and thereafter transfers the data to the page resister PR3 arranged on a subsequent stage. Also, this transfers write data transferred from the page resister PR3 to the corresponding stripe STP.

### <Page Resister PR3>

The page resister PR3 temporarily holds the read data transferred from the first and second stripe buffers SB2 and SB4 and transfers the data to a host not illustrated through an external terminal. Also, the page resister PR3 transfers the write data transferred from the host not illustrated through the external terminal to the first and second stripe buffers SB2 and SB3. Meanwhile, the page resister PR3 is capable of holding 2×2¹⁰+128=2176×8-bit (=17408-bit) data, for example.

### <Second Stripe Buffer SB4>

The second stripe buffer SB4 is provided so as to correspond to the stripe STP as the above-described first stripe buffer SB2. The second stripe buffer SB4 temporarily holds the data read from the stripe STP and thereafter transfers the data to the page resister PR3. Also, this transfers the write data transferred from the page resister PR3 to the corresponding stripe STP.

Meanwhile, a plurality of corresponding peripheral circuits are formed just under the bay B as is described later. Specifically, they are the sense amplifier, a row decoder, a word line driver, a bit line driver and the like.

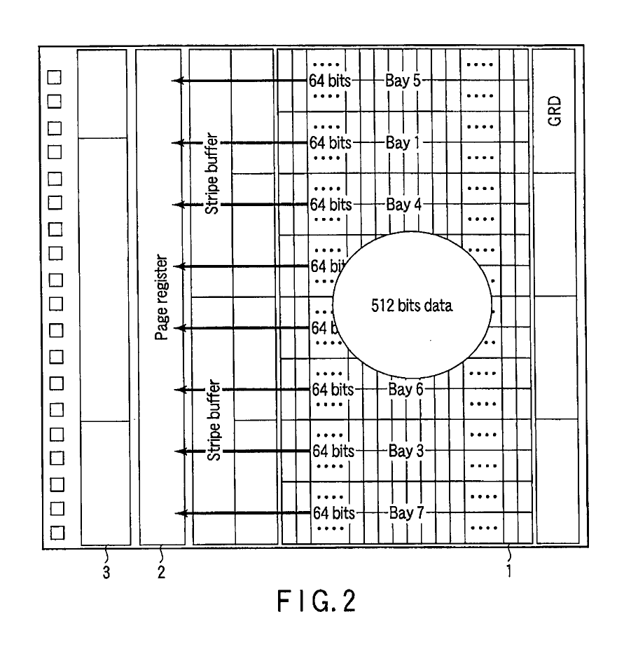

Next, a schematic diagram in which the data read by a sense amplifier SA is output to an external device through the above-described buffer and resister is illustrated in FIG. 2. FIG. 2 is the schematic diagram in which the data is read from the bays B0 to B7 formed in the memory cell array. As illustrated, 64-bit data is read from each bay B by one reading. That is to say, since eight bays B are provided in the semiconductor storage device according to this embodiment, 512-bit (eight bays B×64) data is read by one reading. By repeating this reading 34 times, 512-bit×34=17408-bit data is read. That is to say, after the reading of 34 times, the data is read to outside through the page resister PR3. In this reading, any one block BLK provided in each bay B is made the read target and the 64-bit data is read from the block BLK to outside.

### <Detailed Configuration of Bay B>

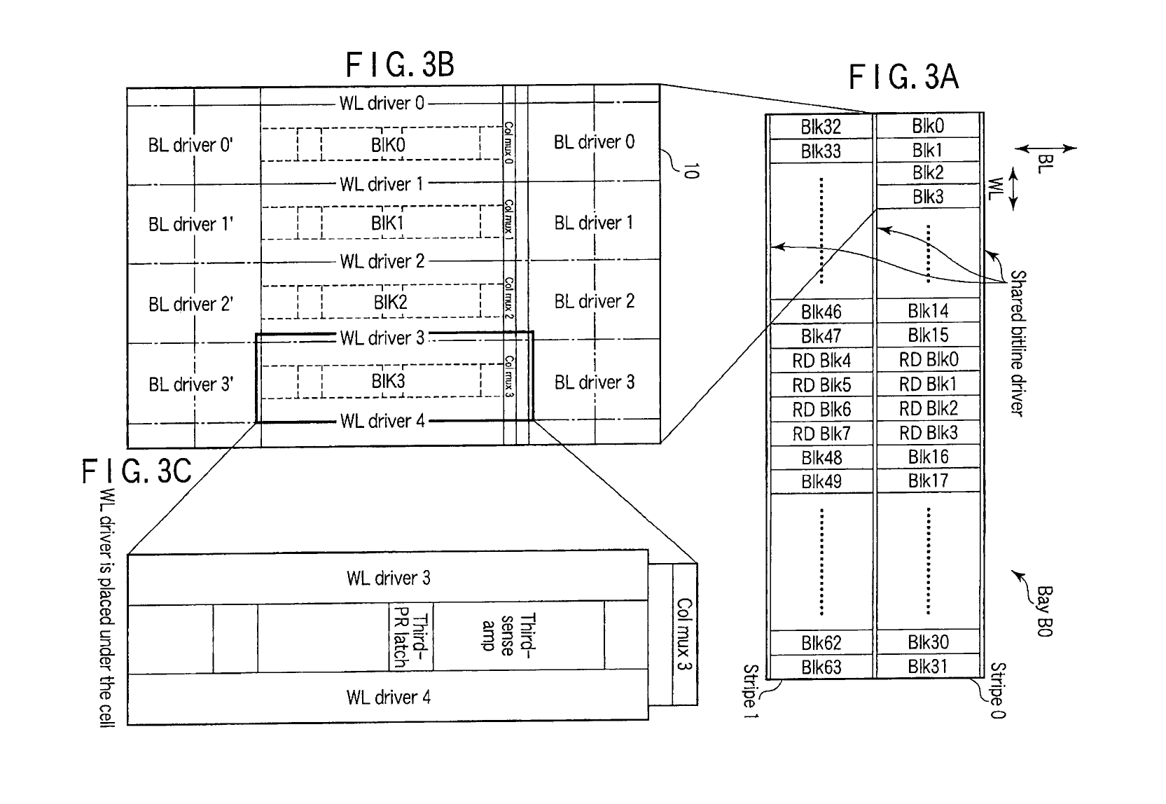

Next, a detailed configuration of the above-described bay B and the peripheral circuits provided under the same is described with reference to FIGS. 3A to 3C. FIG. 3A is a planar view illustrating the bay B0 in detail as an example, FIG. 3B is a planar view of the peripheral circuits illustrating the word line driver, the bit line BL driver and the like located under the bay B0, and FIG. 3C is an enlarged view of FIG. 3B. It is hereinafter described focusing on the bay 0.

As described above, the stripes STP0 and STP1 are provided in the bay B0 as illustrated in FIG. 3A. Also, a plurality of blocks BLK are provided in each of the stripes STP0 and STP1. Specifically, blocks BLK0 to BLK 31 and redundancies RD0 to RD3 (represented as RD BLK) are provided in the stripe STP0, and blocks BLK32 to BLK 63 and redundancies RD4 to RD7 (represented as RD BLK) are provided in the stripe STP1.

For example, the blocks BLK0 and BLK1 in the stripe STP0 share the word line WL and the blocks BLK2 and BLK3 share the word line WL. That is to say, the block BLK2n (0≦n≦15) and the block BLK(2n+1) share the word line WL. The same is true in the stripes STP1 to STP15. Meanwhile, there are a case in which the blocks BLK0 and BLK1 share the word line WL and a case in which the blocks BLK1 and BLK2 share the word line WL. That is to say, focusing on a certain block BLK, a half of the word line WL, which penetrates through the focused block BLK, is shared by an adjacent block BLK on the left and a remaining half of the word line WL is shared by the adjacent block BLK on the right.

Also, in the bay B0, the blocks BLK0 and BLK32 share the bit line BL and the blocks BLK1 and BLK33 share the bit line BL. That is to say, the block BLKn (0≦n≦31) and the block BLK(n+32) share the bit line BL. Further, the block BLK32 and the block BLK0 in the adjacent stripe STP4 share the bit line BL and the block BLK0 and the block BLK32 in the adjacent stripe STP9 share the bit line BL.

It is focused on the block BLK0 as an example. A plurality of memory cells MC are formed in the block BLK0. Each of the memory cells MC includes a rectifying device (diode) DD and a variable resistive element VR. A cathode of the diode DD is connected to the word line WL and an anode of the diode DD is connected to the bit line BL through the variable resistive element VR. The variable resistive element VR is provided with a structure in which a recording layer and a protective layer are sequentially laminated on the diode DD, for example. Also, the configuration of each of the blocks BLK1 to BLK63 is similar to that of the block BLK0, so that the description thereof is omitted. Meanwhile, the memory cell MC will be described later in detail.

### <Planar View of Peripheral Circuit>

Next, the peripheral circuit arranged under a layer on which the above-described block BLK (memory cell MC) is formed is described with reference to FIG. 3B. Herein, it is focused on the peripheral circuits arranged under the blocks BLK0 to BLK3. As illustrated in FIG. 3B, as an example of the peripheral circuits, word line WL drivers 0 to 3, bit line BL drivers 0 to 3, bit line BL drivers 0′ to 3′, and Col muxs 0 to 3 are formed under the memory cell MC. The peripheral circuits are formed on a M1 layer (metal 1) or lower and a global signal line (GSELBt line) to be described later is formed on a M2 layer (metal 2>metal 1). That is to say, the bay B in which the memory cell MC is provided is formed so as to be located between the M1 layer and the M2 layer.

As illustrated in FIG. 3B, the word line WL drivers 0 to 3 are formed in a word line WL direction and the bit line BL drivers are formed in a bit line BL direction. Also, the blocks BLK adjacent to each other are selected by one word line driver WL. For example, the block BLK1 is selected by the word line WL drivers 1 and 2 and the block BLK2 is selected by the word line WL drivers 2 and 3. The same is true in a following description. Meanwhile, an endmost word line WL driver, for example, the word line WL driver 0 selects only the block BLK0.

Further, as for the bit line BL driver, one block BLK is selected by two bit line BL drivers. For example, the bit line BL drivers 0 and 0′ select the block BLK0. Meanwhile, one block BLK is selected in the bay B. Therefore, at the time of the reading of the data from the selected block BLK1, for example, the 64 bit lines are selected by the bit line BL drivers 1 and 1′ corresponding to the selected block BLK1.

Meanwhile, although the peripheral circuits corresponding to the blocks BLK0 to BLK3 are described in FIG. 3, the same is true in the blocks BLK4 to BLK63, so that the description thereof is omitted. Also, when word line WL drivers 0 to 63 are not distinguished from one another, they are simply referred to as the word line WL drivers and when bit line BL drivers 0 to 63 and bit line BL drivers 0′ to 63′ are not distinguished from one another, they are simply referred to as the bit line BL drivers. Similarly, as for the sense amplifier SA and the Col mux to be described later, 64 sense amplifiers SA and 64 Col muxs are formed so as to correspond to the above-described blocks BLK0 to BLK63. Although the sense amplifiers SA and the Col muxs (sometimes also referred to as Col muxs) are referred to as 0th to 63rd sense amplifiers SA and 0th to 63rd Col muxs as needed, when they are not distinguished from one another, they are simply referred to as the sense amplifiers SA and the Col muxs.

Next, the above-described peripheral circuit is described with reference to FIG. 3C, which is the enlarged view of FIG. 3B. Herein, it is focused on the peripheral circuit located just under the block BLK3, for example. As illustrated, the third sense amplifier SA, a third latch circuit LAT (represented as PR latch in the drawing), and a third Col mux, which correspond, are formed just under the block BLK3.

As illustrated in FIG. 3C, the third sense amplifier SA and the third latch LAT circuit are formed so as to be interposed between the above-described word line WL drivers 3 and 4. The third sense amplifier SA formed on the M1 layer or lower is electrically connected to the global signal line formed on the M2 layer through a contact plug CP not illustrated to read 1-bit data, for example, held by the memory cell MC formed in any one block BLK selected from the blocks BLK0 to BLK63. Meanwhile, the global signal line is metal wiring.

The third latch LAT circuit latches the data read by the third sense amplifier SA and outputs the same to the external device through a plurality of above-described buffers, and also, latches the write data supplied from the external device and thereafter supplies the same to the third sense amplifier SA. Meanwhile, another block BLK has the above-described configuration similarly. That is to say, in another block BLK also, the corresponding sense amplifier SA and latch circuit LAT are formed in the block. That is to say, as for the sense amplifier SA, up to the 63rd sense amplifier SA are provided and as for the latch LAT circuit, up to the 63rd latch LAT circuit are provided.

### <Detail of Memory Cell Array>

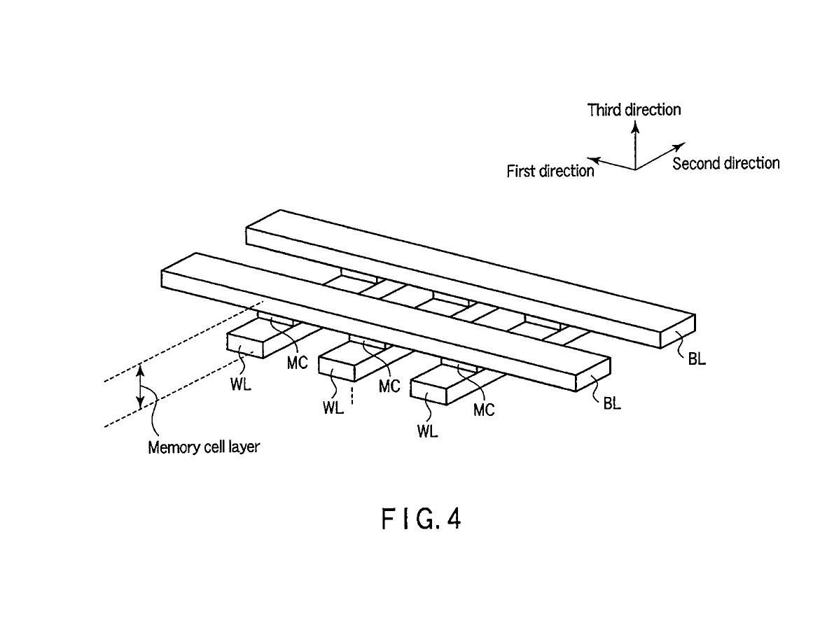

Next, a detailed configuration example of the memory cell array formed in the block BLK is described with reference to FIG. 4. FIG. 4, which is a perspective view of a partial area of the memory cell array, illustrates a state in which the memory cell array is configured in a three-dimensional manner. As illustrated, the memory cell array according to this embodiment is formed in the order of the word line WL, the memory cell MC, and the bit line BL in a direction perpendicular to a surface of a semiconductor substrate (third direction); however, it is also possible that a group of the word line WL, the memory cell MC, and the bit line BL (hereinafter, memory cell layer) is such that they are laminated through an interlayer insulating film. Although it is described such that only one memory cell layer is formed in the block BLK in this embodiment, it is also possible that a plurality of memory cell layers are laminated in the third direction.

### <Circuit Diagram of Memory Cell Array>

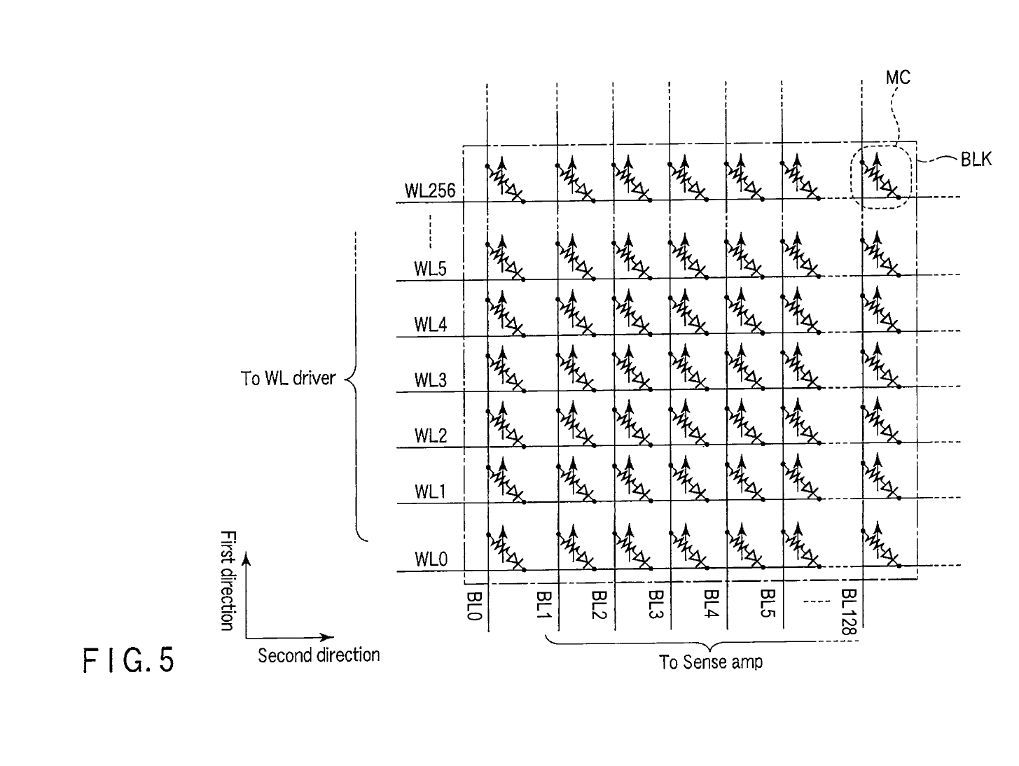

Next, a circuit example of the above-described memory cell array 1 is described with reference to FIG. 5. As described above, a plurality of bit lines BL and word lines WL are formed in the memory cell array 1 so as to penetrate through the block BLK. The block BLK includes 128 bit lines BL, for example, and 256 word lines WL, for example, as described above. That is to say, bit lines BL(128i) to BL(128i+128) are formed in a certain block BLKi (wherein i=0 to n).

Also, as described above, the memory cell MC is formed on the intersection of the bit line BL and the word line WL.

Also, the above-described word line WL is connected to the word line WL driver and the bit line BL is connected to the sense amplifier SA through the bit line BL driver and the Col mux.

### <Electric Property of Memory Cell MC>

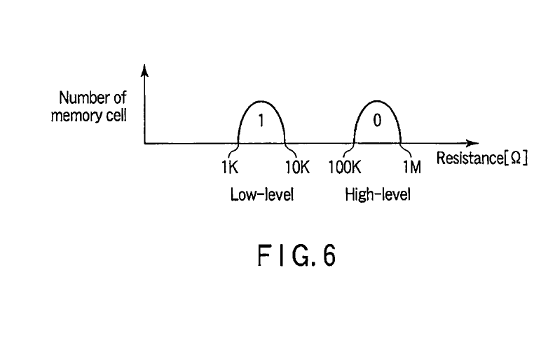

Next, an electric property of the above-described memory cell MC is described with reference to FIG. 6. As described above, the memory cell MC may take a low-resistive state and a high-resistive state according to the resistance value of the variable resistive element VR. The memory cell MC is in a state of holding “1” in the low-resistive state and in a state of holding “0” data in the high-resistive state. Also, a state in which the resistance value is 1 k to 10 kΩ, for example, is made the low-resistive state and a state in which the resistance value is 100 k to 1 MΩ, for example, is made the high-resistive state.

### <Circuit Diagram of Bay B>

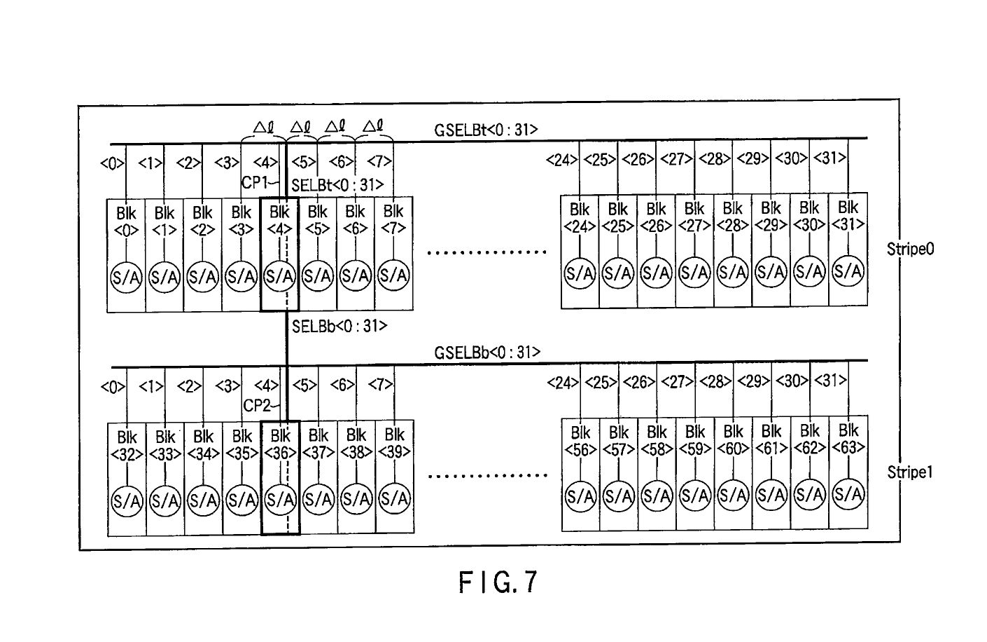

Next, a circuit diagram of the above-described bay B is described with reference to FIG. 7. Specifically, the global signal lines arranged on the M2 layer (GSELBt<0:31> or GSELBb<0:31> in the drawing, hereinafter, referred to as the “global signal lines (GSELBt, GSELBb), and when they are not distinguished from each other, simply referred to as the global signal lines (GSELB)), the sense amplifier SA arranged on the M1 layer, the block BLK formed between the M1 layer and the M2 layer, the contact plug CP, which connects the global signal line and the sense amplifier SA, and the contact plug CP, which connects the global signal line and the bit line BL, are described. Herein, it is described focusing on the bay B0 as an example. That is to say, it is focused on the stripes STP0 and STP1.

As described above, the stripe STP0 is provided with the blocks BLK0 to BLK31 and the stripe STP1 is provided with the blocks BLK32 to BLK63 as illustrated in FIG. 7. In this embodiment, it is described focusing on the blocks BLK4 and BLK36 enclosed by a thick frame. Also, since another block BLK has the configuration similar to that of the blocks BLK4 and BLK36, the description thereof is omitted.

As illustrated, the 128 bit lines BL, for example, penetrate through the block BLK4 (also penetrate through the block BLK36). As described above, the data read from one block BLK at one time is the 64-bit data, so that the number of bit lines used at the time of reading is set to 64. That is to say, out of the 128 bit lines BL penetrating through the blocks BLK4 and BLK36, 32 bit lines BL are electrically connected to the global signal lines (GSELBt<0:31> in the drawing) through the contact plug CP, a SELBt line, and the Col mux not illustrated. Herein, the contact plug CP and the SELBt line connected to the 32 bit lines BL are collectively simply referred to as the SELBt line. The SELBt line acts as a local signal line as opposed to the global signal line.

Next, out of the 64 bit lines BL, remaining 32 bit lines BL are also electrically connected to the global signal lines (GSELBb<0:31> in the drawing) through the contact plug CP, a SELBb line, and the Col mux not illustrated. Herein, the contact plug CP and the SELBb line not illustrated connected to the remaining 32 bit lines BL are collectively simply referred to as the SELBb line. That is to say, the blocks BLK4 and BLK36, which share the bit lines BL, are electrically connected to the global signal lines (GSELBt, GSELBb) through the SELBt line and the SELBb line, respectively. The SELBb line also acts as the local signal line as opposed to the global signal line as the SELBt line.

The fourth sense amplifier SA is connected to the global signal line (GSELBt) through a contact plug CP1. Also, the 36th sense amplifier SA is connected to the global signal line (GSELBb) through a contact plug CP2. That is to say, the data read from the fourth block BLK, for example, to the global signal lines (GSELBt, GSELBb) through the SELBt line and the SELBb line, respectively, is transferred to a total of 64 sense amplifiers SA including the 4th and 36th sense amplifiers SA through the contact plugs CP1 and CP2.

<Distance from Read Target Block BLK to Each Sense Amplifier SA>

Next, a wiring length l of the global signal line required for the data held by the read target block BLK to be sensed by the 0th to 63rd sense amplifiers SA is described with reference to FIG. 7. A value of the wiring length l is set to a value variable according to a position of the block BLK, which is made the read target, and an arranging position of the sense amplifier SA. Meanwhile, herein also, it is described focusing on the fourth block BLK. Meanwhile, the SELBt line and the SELBb line have the same length and the contact plugs CP1 and CP2, which connect each sense amplifier SA to the global signal lines (GSELBt, GSELBb), have the same length.

In this manner, as the block BLK is farther from the block BLK4, which is the read target of the data, on the center to right and left one by one, a distance of the global signal line (GSELBt, GSELBb), which connects the sense amplifier SA arranged just under the block BLK and the block BLK4, becomes longer at a constant increment. When the wiring length of the global signal line is set to a distance l₁, a required distance l₁ increases at a constant increment as the distance from the block BLK4 to the sense amplifier SA becomes longer, for example. Meanwhile, out of the sense amplifiers SA in the stripe STP0, the 31st sense amplifier SA has the longest distance l₁ from the block BLK4 and the 4th sense amplifier SA arranged just under the block BLK4 has the shortest distance l₁. Also, when the distance l₁ of the wiring length increased for shift of one sense amplifier SA is set to Δl, the wiring length l₁ to the 31st sense amplifier SA is set to Δl×(27+4). Meanwhile, it is herein set to “+4” because four redundancies RD illustrated in FIG. 3A are taken into account.

Meanwhile, as for the 32nd to 63rd sense amplifiers SA provided in the stripe STP1, the SELBt line and the global signal line (GSELBt) in the 0th to 31st sense amplifiers SA in the above-described stripe STP0 may be replaced with the SELBb line and the global signal line (GSELBb), respectively. This is because the SELBb line and the SELBt line have the same length and the contact plug CP, which connects each of the 32nd to 63rd sense amplifiers SA to the global signal line (GSELBb) has the same length as the contact plug CP in the above-described stripe STP0. Therefore, the distance l₁ from the 32nd sense amplifier SA, for example, to the block BLK4 is the same as a case of the 0th sense amplifier SA and the distance l₁ from the 63rd sense amplifier SA, for example, to the block BLK4 is the same as a case of the 31st sense amplifier SA.

In this manner, the wiring length of the global signal, that is to say, the parasitic resistance corresponding to the wiring length changes according to the arranging positions of the read target block BLK and the sense amplifier SA. In this embodiment, the reference current flowing to the sense amplifier SA is compensated according to the parasitic resistance changing in this manner. This will be described later in detail.

### <Detailed Example of Circuit>

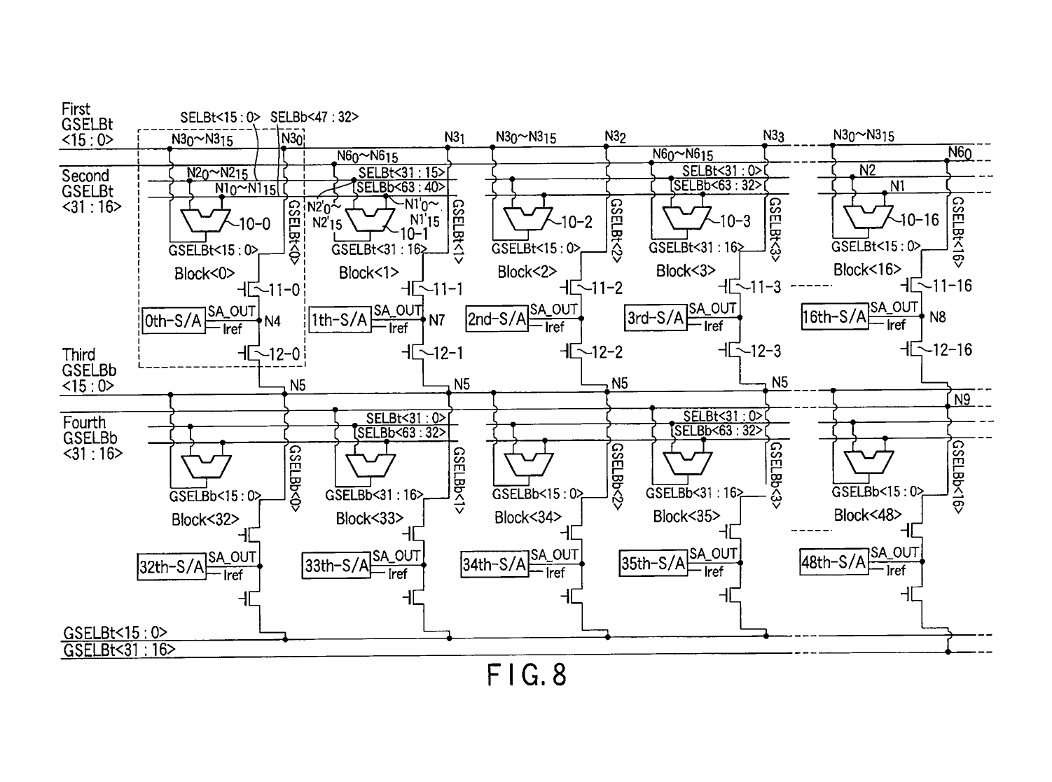

Next, the circuit diagram illustrated in FIG. 7 is described in detail with reference to FIG. 8. Herein, it is focused on a part of the stripes STP0 and STP1 illustrated in FIG. 7. Specifically, the blocks BLK0 to BLK3, BLK16, BLK32 to BLK35, and BLK48 are described. Meanwhile, another block BLK has the similar circuit, so that the description thereof is omitted. Meanwhile, out of the above-described global signal lines (GSELBt), the signal lines, which transfer 0th-bit to 15th-bit signals, are referred to as first global signal lines and the signal lines, which transfer remaining 16th-bit to 31st-bit signals, are referred to as second global signal lines. First, an area of the block BLK0 is described.

As illustrated in FIG. 8, in the area of the block BLK0 (represented as Block<0> in the drawing), the 0th sense amplifier SA, the Col mux 10-0 (identical to the Col mux 0 in FIG. 3B), an n-channel MOS transistor 11-0, and an n-channel MOS transistor 12-0 formed on the M1 layer or lower are formed in addition to the global signal line. Meanwhile, the bit line BL driver and the word line WL driver are herein not illustrated.

As illustrated in FIG. 8, the Col mux 10-0 is connected to SELBb lines<47:32> at a node N1 and is connected to SELBt lines<15:0> at a node N2. Herein, although a connecting point of the SELBb lines<47:32> and one input terminal of the Col mux is made the node N1, there are actually 16 Col muxs 10-0 connected to the node N1 and there are 16 connecting points connected to the Col muxs 10-0. That is to say, the Col muxs 10-0 are connected to the SELBb lines <47:32> at nodes N1₀ to N1₁₅, respectively. Also, 16 SELBt lines are input to one input terminals of the Col muxs 10-0. The same is true in the node N2 and this is common in all the block BLK areas. That is to say, the Col muxs 10-0 are connected to the SELBb lines<15:0> at nodes N2₀ to N2₁₅, respectively.

Each of the Col muxs 10-0 selects either the above-described SELBt lines<15:0> or the SELBb lines<47:32> and transfers 16-bit data of the selected signal lines to the first global signal lines (first GSELBt<15:0> in the drawing) connected at a node N3. Herein, although this is set to the node N3, since there are 16 Col muxs 10-0, there are actually 16 connecting points as the nodes N1 and N2. That is to say, output terminals of the Col muxs 10-0 are connected to the first global signal lines<15:0> at nodes N3₀ to N3₁₅, respectively, to transfer the 16-bit data to the first global signal lines through the nodes N3₀ to N3₁₅, respectively.

One end of a current pathway of the MOS transistor 11-0 is connected to the signal line, which transfers the 0th-bit data (GSELBt<0> in the drawing), out of the first global signal lines including 16 signal lines at the node N3₀ and the other end thereof is connected to a node N4. A control signal (signal STR_ADD*EN_SA to be described later) for turning on/off the MOS transistor 11-0 is supplied to a gate thereof. A signal line SA_OUT is connected to the node N4 and the 0th sense amplifier SA reads the data by comparing the current flowing to the node N4 with a reference current Iref. One end of the current pathway of the MOS transistor 12-0 is connected to the node N4, the other end thereof is connected to any one of the global signal lines (GSELBb<15:0>) at a node N5 and a control signal (signal XSTR_ADD*EN_SA to be described later) for turning on/off the MOS transistor is supplied to the gate thereof.

Next, a circuit example in an area of the block BLK1 (represented as Block<1> in the drawing) adjacent to the above-described block BLK0 is described. Meanwhile, the configuration identical to that of the area of the block BLK0 is not described. As illustrated in FIG. 8, in the area of the block BLK1, the first sense amplifier SA, a Col mux 10-1, an re-channel MOS transistor 11-1, and an n-channel MOS transistor 12-1 are formed.

The 16 Col muxs 10-1 are connected to SELBb lines<63:48> at nodes N1′₀ to N1′₁₅ and are connected to SELBt lines<32:15> at nodes N2′₀ to N2′₁₅. That is to say, each of the Col muxs 10-1 selects either the SELBt lines<63:48> or the SELBb lines<31:15> and transfers the 16-bit data of the selected signal lines to the second global signal lines (GSELBt<31:16> in the drawing) connected at nodes N6₀ to N6₁₅.

One end of the current pathway of the MOS transistor 11-1 is connected to the signal line, which transfers the 1st-bit data (GSELBt<1> in the drawing), out of the first global signal lines including the 16 signal lines at the node N3₁, the other end thereof is connected to a node N7, and the control signal for turning on/off the MOS transistor 11-1 (signal STR_ADD*EN_SA to be described later) is supplied to the gate thereof. The signal line SA_OUT is connected to the node N7 and the first sense amplifier SA senses the current flowing to the node N7 using the reference current Iref. One end of the current pathway of the MOS transistor 12-1 is connected to the node N7, the other end thereof is connected to any one of the global signal lines (GSELBb<15:0>) at the node N5, and the control signal (signal XSTR_ADD*EN_SA to be described later) for turning on/off the MOS transistor 12-1 is supplied to the gate thereof.

Although the global signal lines (GSELBt, GSELBb) and the circuit example of the peripheral circuits in the areas in which the blocks BLK0 and BLK1 are provided are described above, since the connection is similar for the blocks BLK2 to BLK15 and BLK32 to BLK47, this is not described. Also, when the MOS transistors 11-0 to 11-63 formed just under the areas of the blocks BLK0 to BLK63 are not distinguished from one another, they are simply referred to as the MOS transistors 11, and also, when the MOS transistors 12-0 to 12-63 are not distinguished from one another, they are simply referred to as the MOS transistors 12. Further, the control signal (signal STR_ADD*EN_SA) supplied to the gates of the MOS transistors 11-0 and 11-1 is also supplied to other MOS transistors 11-2 to 11-63 similarly. Similarly, the control signal (signal XSTR_ADD*EN_SA) supplied to the gates of the MOS transistors 12-0 and 12-1 also is supplied to other MOS transistors 12-2 to 12-63 similarly.

Next, the circuit example in the area in which the block BLK16 is provided is described. As illustrated, in the area of the block BLK16, a Col mux 10-16, an n-channel MOS transistor 11-16, an n-channel MOS transistor 12-16, and the 16th sense amplifier SA are provided in addition to the global signal line (GSELBt). Meanwhile, the contents similar to the above-described configuration are not described.

As illustrated in FIG. 8, one end of the current pathway of the MOS transistor 11-16 is connected to the signal line, which transfers the 17th-bit data (GSELBt<16> in the drawing), out of the second global signal lines including 16 signal lines at the node N6₀ and the other end thereof is connected to a node N8. Meanwhile, although the connecting point of one end of the current pathway of the MOS transistor 11-16 and the global signal line (GSELBt) is made the node N6, as illustrated in FIG. 8 also, there are 16 second global signal lines (GSELBt). That is to say, the second global signal lines also include the signal lines (GSELBt<17> to GSELBt<31> not illustrated), which transfer the 18th-bit to 32nd-bit data, in addition to the GSELBt<16> and the signal lines are connected to the MOS transistors 11-17 to 11-31 of the corresponding blocks BLK17 to BLK31 at the nodes N6₁ to N6₁₅, respectively. The control signal for turning on/off the MOS transistor 11-16 is supplied to the gate of the MOS transistor 11-16. The signal line SA_OUT is connected to the node N8, and the 16th sense amplifier SA reads the data by comparing the current at the node N8 and the reference current Iref. One end of the current pathway of the MOS transistor 12-16 is connected to the node N8, the other end thereof is connected to any one of third global signal lines (GSELBb<15:0> at a node N9, and the control signal for turning on/off the MOS transistor 12-16 is supplied to the gate thereof.

Although the circuit example provided in the stripe STP0 is described above, the stripe STP1 has the similar configuration, so that the description thereof is omitted. That is to say, the third global signal lines (GSELBb<15:0> in the drawing) are connected to one ends of the current pathways of the 32nd to 47th sense amplifiers SA in the areas in which the blocks BLK32 to BLK47 are provided, respectively, and fourth global signal lines (GSELBb<31:16> in the drawing) are connected to one ends of the current pathways of the 48th to 61st sense amplifiers SA in the areas in which the blocks BLK48 to BLK61 are provided, respectively.

### <Specific Circuit Example of Read Pathway>

Next, a detailed circuit diagram until the data is read from the memory cell by the 0th sense amplifier SA, for example, in the above-described configuration is described. That is to say, the current of the global signal line (GSELBt<0>) out of the global signal lines (GSELBt<15:0> in the drawing) is sensed by the 0th sense amplifier SA.

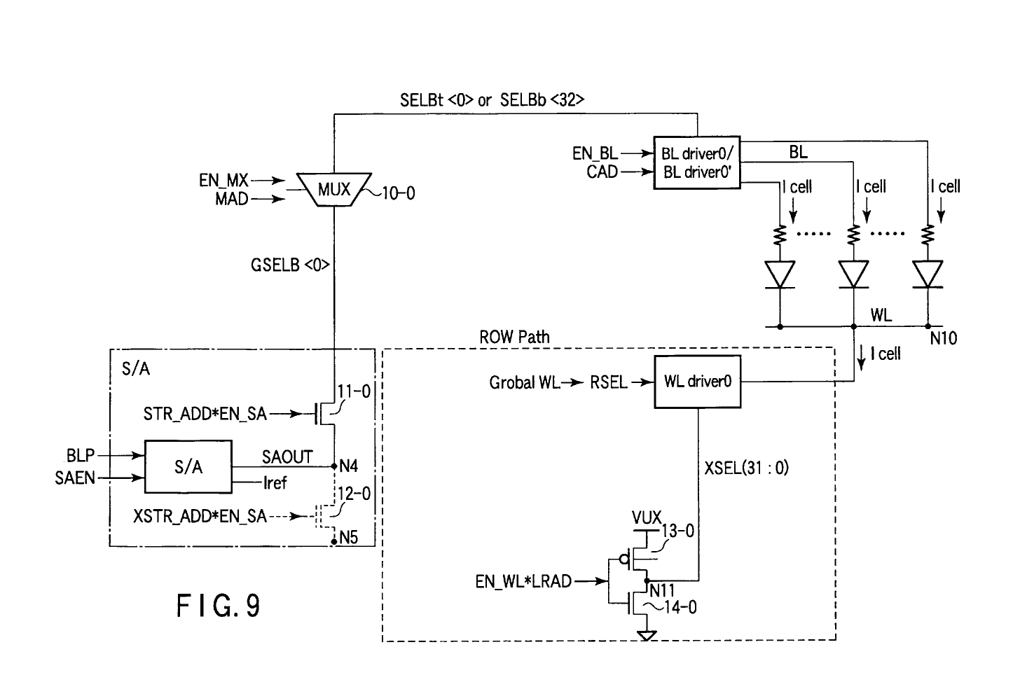

As illustrated in FIG. 9, the 0th sense amplifier SA, the n-channel MOS transistors 11-0, 12-0, and 14-0, a p-channel MOS transistor 13-0, the Col mux 10-0, the bit line BL driver 0, the word line WL driver 0, the word line WL driver 0′, and the memory cell MC are provided.

As described above, the node N4 is connected to an output terminal of the 0th sense amplifier SA and a signal BLP and a signal SAEN are input to the 0th sense amplifier SA. Also, the reference current Iref is supplied to the 0th sense amplifier SA. That is to say, the 0th sense amplifier SA compares the current at the node N4 and the reference current Iref to read the data held by the memory cell MC. Meanwhile, the reference current Iref will be described later. One end of the current pathway of the MOS transistor 12-0 is connected to the node N4, the other end thereof is connected to the node N5, and the signal XSTR_ADD*EN_SA is input to the gate thereof. One end of the current pathway of the MOS transistor 11-0 is connected to the node N4, the other end thereof is connected to the global signal line (represented as GSELBt<0> in the drawing), and the signal STR_ADD*EN_SA is input to the gate thereof.

As described above, the Col mux 10-0 selects either signal line of the SELBt line<0> or the SELBb line<32> to transfer the 1-bit data to the global signal line (GSELBt<0>). A signal EN_MX and a signal MAD are input to the MUX10-0.

A signal EN_BL and a signal CAD are input to the bit line BL driver 0. Also, the bit line BL driver 0 selects one of the above-described SELBt line<0> and the SELBt line<32> and connects the same to the 32 bit lines BL. Next, as described above, the bit line BL driver 0′ also selects the 32 bit lines BL. According to this, the 64-bit data is read from one block BLK.

Meanwhile, it is also possible that the bit line BL driver is provided for each bit line BL. The other end of the bit line BL is connected to one end of the variable resistive element VR and the other end thereof is connected to the anode of the diode DD. The cathode of the diode DD is connected to the word line WL at a node N10 and the node 10 is connected to an output terminal of the word line WL driver. A signal RSEL transferred from a global word line WL (Grobal WL in the drawing) is supplied to the word line WL driver. Signal lines XSEL (31:0) are further connected to the word line WL driver 0. The signal lines XSEL (31:0) are connected to a node N11. Meanwhile, the global word line WL is the word line WL, which penetrates through the stripe STP0.

A signal VUX is supplied to one end of the current pathway of the p-channel MOS transistor 13-0, the other end of the current pathway is connected to the node N11, and a signal EN_WL*LRAD is supplied to the gate thereof. Also, the node N11 is connected to one end of the current pathway of the n-channel MOS transistor 14-0, the other end of the current pathway is grounded, and the signal EN_WL*LRAD is supplied to the gate thereof.

### <Read Operation of Data>

Next, read operation of the data in the above-described configuration is simply described. First, when the word line WL driver is selected by the signal RSEL transferred from the global word line WL, the word line WL driver sets potential of the word line WL to an “H” level through the node N10. Meanwhile, at that time, the bit line BL is in a non-selected state, that is to say, the potential thereof remains to be an “L” level.

Next, the bit line BL is precharged to be put into a selected state. That is to say, a signal SAOUT is set to the “H” level by the 0th sense amplifier SA. This voltage is transferred to the bit line driver 0 through the MOS transistor 11-0, the global signal line (GSELBt), the Col mux 10-0, and the SELB line. The bit line driver 0 supplies the transferred “H” level to the selected bit line BL. According to this, the bit line BL is set to the “H” level.

Next, the word line WL is put into the selected state by the word line driver 0. That is to say, by setting the XSEL line to the “L” level, transition of the potential of the word line WL from the “H” level so far to the “L” level is performed. Specifically, the signal EN_WL*LRAD is set to the “H” level and the node N11 is grounded.

When a value of the variable resistive element VR is small, that is to say, in the low-resistive state, a current Icell_on flows to the memory cell MC. That is to say, the current Icell_on flows to the word line WL. That is to say, the current Icell_on flows to the 0th sense amplifier SA, the MOS transistor 11-0, the global signal line (GSELBb), the Col mux 10-0, the SELB line, the bit line BL driver 0, the bit line BL, the memory cell MC, and the word line WL. The 0th sense amplifier SA compares the reference current Iref with the current Icell_on flowing to the node N4 to read the data held by the memory cell MC.

Also, if the value of the variable resistive element VR is large, that is to say, when the memory cell MC is in the high-resistive state, a current Icell_off flows to the memory cell MC. The 0th sense amplifier SA compares the current Icell_off flowing to the node N4 with the reference current Iref to read the data held by the memory cell MC. Next, the circuit configuration to generate the above-described reference current Iref is described.

### <Reference Current Generating Circuit>

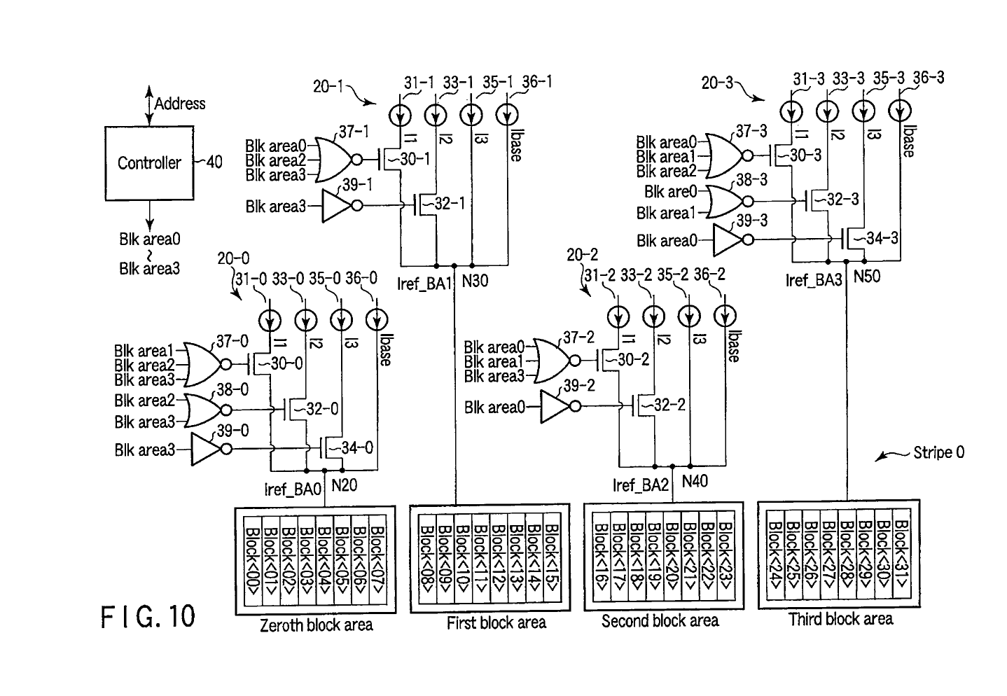

In this embodiment, the value of the above-described reference current Iref is controlled according to the length of the distance l₁ (parasitic resistance) of the global signal line. Hereinafter, a specific configuration thereof is described with reference to FIG. 10.

FIG. 10 illustrates an arranging position of the block BLK and a configuration of a reference current generating circuit, which generates the reference current Iref to be supplied to the sense amplifier SA. As illustrated in FIG. 10, the blocks BLK0 to BLK31, reference current generating circuits 20-0 to 20-3, and a controller 40 are provided. Meanwhile, although it is illustrated such that currents Iref_BA0 to BA3 are supplied to each block BLK in FIG. 10, as described above, the currents Iref_BA0 to BA3 are actually supplied to the sense amplifiers SA provided just under the blocks BL. Also, the currents Iref_BA0 to BA3 are set to different values and the current values are controlled by a control signal to be described later. Herein, it is described focusing on the stripe STP0 formed in the bay B0.

As illustrated, the blocks BLK0 to BLK31 in the stripe STP0 are divided into four areas, for example. That is to say, it is divided such that the blocks BLK0 to BLK7 are a 0th block BLK area, the blocks BLK8 to BLK15 are a first block BLK area, the blocks BLK16 to BLK23 are a second block BLK area, and the blocks BLK24 to BLK31 are a third block BLK area.

The reference current generating circuit 20-0 corresponds to the 0th block BLK area and supplies the reference current Iref_BA0 to the sense amplifier SA provided just under the 0th block BLK area. The reference current generating circuit 20-0 is provided with n-channel MOS transistors 30-0, 32-0, and 34-0, current sources 31-0, 33-0, 35-0, and 36-0, NOR circuits 37-0 and 38-0, and an inverter 39-0.

A current I1 is supplied from the current source 31-0 to one end of the current pathway of the MOS transistor 30-0, the other end of the current pathway is connected to a node N20, and an operation result by the NOR circuit 37-0 is supplied to the gate thereof. The NOR circuit 37-0 performs NOR operation of signals Blk area1, Blk area2, and Blk area3. A current I2 by the current source 33-0 is supplied to one end of the current pathway of the MOS transistor 32-0, the other end of the current pathway is connected to the node N20, and the operation result by the NOR circuit 38-0 is supplied to the gate thereof. The NOR circuit 38-0 performs the NOR operation of the signals Blk area2 and Blk area3. A current I3 by the current source 35-0 is supplied to one end of the current pathway of the MOS transistor 34-0, the other end of the current pathway is connected to the node N20, and a signal output from the inverter 39-0 is supplied to the gate thereof. The inverter 39-0 inverts the signal Blk area3. Also, the current source 36-0 supplies a current Ibase to the node N20.

Next, a configuration of the reference current generating circuit 20-1 is described. The reference current generating circuit 20-1 corresponds to the first block BLK area and supplies the reference current Iref_BA1 to the sense amplifier SA provided just under the first block BLK area. The reference current generating circuit 20-1 is provided with n-channel MOS transistors 30-1 and 32-1, current sources 31-1, 33-1, 35-1, and 36-1, a NOR circuit 37-1, and an inverter 39-1.

The current I1 is supplied from the current source 31-1 to one end of the current pathway of the MOS transistor 30-1, the other end of the current pathway is connected to a node N30, and the operation result by the NOR circuit 37-1 is supplied to the gate thereof. The NOR circuit 37-1 performs the NOR operation of the signals Blk area0, Blk area2, and Blk area3. A current I2 by the current source 33-1 is supplied to one end of the current pathway of the MOS transistor 32-1, the other end of the current pathway is connected to the node N30, and an inverted signal output from the inverter 39-1 is supplied to the gate thereof. The inverter 39-1 inverts the signal Blk area3. Also, the current sources 35-1 and 36-1 supply the current I3 and the current Ibase to the node N20.

Next, the configuration of the reference current generating circuit 20-2 is described. The reference current generating circuit 20-2 corresponds to the second block BLK area and supplies the reference current Iref_BA2 to the sense amplifier SA provided just under the second block BLK area. The reference current generating circuit 20-2 is provided with re-channel MOS transistors 30-2 and 32-2, current sources 31-2, 33-2, 35-2, and 36-2, a NOR circuit 37-2, and an inverter 39-2.

The current I1 is supplied from the current source 31-2 to one end of the current pathway of the MOS transistor 30-2, the other end of the current pathway is connected to a node N40, and the operation result by the NOR circuit 37-2 is supplied to the gate thereof. The NOR circuit 37-2 performs the NOR operation of the signals Blk area0, Blk area1, and Blk area3. The current I2 by the current source 33-2 is supplied to one end of the current pathway of the MOS transistor 32-2, the other end of the current pathway is connected to the node N40, and an inverted signal output from the inverter 39-2 is supplied to the gate thereof. The inverter 39-2 inverts the signal Blk area0. Also, the current sources 35-2 and 36-2 supply the current I3 and the current Ibase to the node N40.

Further, the reference current generating circuit 20-3 is described. The reference current generating circuit 20-3 corresponds to the third block BLK area and supplies the reference current Iref_BA3 to the sense amplifier SA provided just under the third block BLK area. The reference current generating circuit 20-3 is provided with n-channel MOS transistors 30-3, 32-3, and 34-3, current sources 31-3, 33-3, 35-3, and 36-3, NOR circuits 37-3 and 38-3, and an inverter 39-3.

The current I1 is supplied from the current source 31-3 to one end of the current pathway of the MOS transistor 30-3, the other end of the current pathway is connected to a node N50, and the operation result by the NOR circuit 37-3 is supplied to the gate thereof. The NOR circuit 37-3 performs the NOR operation of the signals Blk area0, Blk area1, and Blk area2. The current I2 by the current source 33-3 is supplied to one end of the current pathway of the MOS transistor 32-3, the other end of the current pathway is connected to the node N50, and the operation result by the NOR circuit 38-3 is supplied to the gate thereof. The NOR circuit 38-3 performs the NOR operation of the signals Blk area0 and Blk area1. The current I3 by the current source 35-3 is supplied to one end of the current pathway of the MOS transistor 34-3, the other end of the current pathway is connected to the node N50, and a signal output from the inverter 39-3 is supplied to the gate thereof. The inverter 39-3 inverts the signal Blk area0. Also, the current source 36-3 supplies the current Ibase to the node N50.

Next, the controller 40 is described. The controller 40 manages the blocks BLK0 to BLK31 in the stripe STP. The blocks BLK0 to BLK31 are divided into a plurality of aggregations by the formed circuit configuration. Therefore, the controller 40 manages a plurality of aggregations divided by the circuit configuration. That is to say, as illustrated in FIG. 10, the controller 40 manages each divided aggregation of the blocks BLK0 to BLK7, . . . , and the blocks BLK24 to BLK31, for example. Specifically, the controller 40 manages to which aggregation a certain block BLK belongs. Meanwhile, although the blocks BLK0 to BLK31 are divided into four in this embodiment, it is also possible to divide the same into two or three or more. At that time, it is required to provide the reference current generating circuits 20 as many as divisions of the blocks BLK.

Further, the controller 40 receives an address from the external device (host) and decodes the signals BLK area0 to BLK area3 to know which block is the block, which is made the read target. That is to say, when the controller 40 receives a read address, this grasps the block BLK, which is made the read target, based on a decoded. That is to say, this grasps which block BLK of the above-described blocks BLK0 to BLK63 is made the read target. As described above, the controller 40 manages to which aggregation a certain block BLK belongs. That is to say, the controller 40 generates either the “L” level or the “H” level for the above-described signals BLK area0 to BLK area3 according to the read address. According to this, the reference current generating circuits 20-0 to 20-3 may generate an appropriate reference current Iref corresponding to the block BLK, which is made the read target.

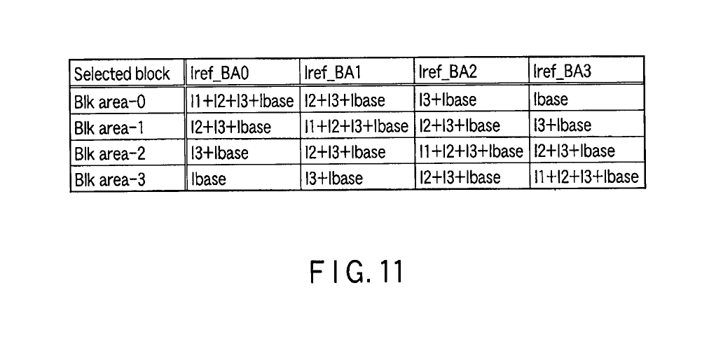

The controller 40 may also grasp the wiring length l of the global signal line from the read target block BLK to each sense amplifier SA from the read address. This is because the controller 40 grasps a circuit arrangement of each sense amplifier SA and arrangement of the circuit configuration of each block BLK, so that this may recognize the distance from each sense amplifier SA to the block BLK, which is made the read target. In this case, the controller 40 generates the signals BLK area0 to BLK area3 according to the wiring length l. Next, the reference current Iref generated by the reference current generating circuits 20-0 to 20-3 according to the selected block BLK in the above-described configuration is described with reference to FIG. 11. FIG. 11 is a table in which relationship between the 0th to 3rd block BLK areas and the reference current flowing to the sense amplifiers SA corresponding to the 0th to 3rd block BLK areas when they are selected.

The values of the reference currents Iref_BA0 to Iref_BA3 when any block BLK of the 0th block BLK area is put into the selected state are indicated in FIG. 11. That is to say, a case in which any one of the blocks BLK0 to BLK7 is made the read target is supposed. In this case, since the signals BLK area1 to BLK area3 are set to the “L” level, the MOS transistors 30-0, 32-0, and 34-0 are put into an on state (refer to FIG. 10). Therefore, the value of the reference current Iref_BA0 at the node N20 is set to I1+I2+I3+Ibase. Also, since the signal Blk area0 is set to the “H” level, the MOS transistor 30-1 is put into an off state and the MOS transistor 32-1 is put into the on state (refer to FIG. 10). Therefore, the value of the reference current Iref_BA1 at the node N30 is set to I2+I3+Ibase. Similarly, the value of the reference current Iref_BA2 at the node N40 is set to I3+Ibase and the value of the reference current Iref_BA3 at the node N50 is set to Ibase.

Next, the values of the reference currents Iref_BA0 to Iref_BA3 when any block BLK of the first block BLK area is put into the selected state are indicated. That is to say, a case in which any one of the blocks BLK8 to BLK15 is made the read target is supposed. In this case, the signal Blk area1 is set to the “H” level and the signals Blk area0, Blk area2, and Blk area3 are set to the “L” level. Therefore, the NOR circuit 38-0 and the inverter 39-0 output the “H” level. Therefore, the MOS transistors 32-0 and 34-0 are put into the on state (refer to FIG. 10) and the value of the reference current Iref_BA0 flowing to the node N20 is set to I2+I3+Ibase. Similarly, in the reference current generating circuit 20-1, the MOS transistors 30-1 and 32-1 are put into the on state (refer to FIG. 10). Therefore, the value of the reference current Iref_BA1 is set to I1+I2+I3+Ibase, the value of the reference current Iref_BA2 is set to I2+I3+Ibase, and the value of the reference current Iref_BA3 is set to I3+Ibase.

Next, the values of the reference currents Iref_BA0 to Iref_BA3 when any block BLK of the second block BLK area is put into the selected state are indicated. That is to say, a case in which any one of the blocks BLK16 to BLK23 is made the read target is supposed. In this case, the signals Blk area0, BLK area1, and BLK area3 are set to the “L” level and the signal Blk area2 is set to the “H” level. Therefore, in the reference current generating circuit 20-0, the MOS transistors 30-0, 32-0, and 34-0 are put into the on state (refer to FIG. 10). Therefore, the value of the reference current Iref_BA0 at the node N20 is set to I3+Ibase. Similarly, in the reference current generating circuit 20-1, the MOS transistors 30-1 is put into the off state and the MOS transistor 32-1 is put into the on state (refer to FIG. 10). Therefore, the value of the reference current Iref_BA1 at the node N30 is set to I2+I3+Ibase. Similarly, the value of the reference current Iref_BA2 at the node N40 is set to I1+I2+I3+Ibase and the value of the reference current Iref_BA3 at the node N50 is set to I2+I3+Ibase.

Further, the values of the reference currents Iref_BA0 to Iref_BA3 when any block BLK of the third block BLK area is put into the selected state are indicated. That is to say, a case in which any one of the blocks BLK24 to BLK31 is made the read target is supposed. In this case, the signals Blk area0 to BLK area2 are set to the “L” level and the signal Blk area3 is set to the “H” level. Therefore, in the reference current generating circuit 20-0, the MOS transistors 30-0, 32-0, and 34-0 are put into the off state (refer to FIG. 10). Therefore, the value of the reference current Iref_BA0 at the node N20 is set to Ibase. Similarly, in the reference current generating circuit 20-1, the MOS transistors 30-1 and 32-1 are put into the off state (refer to FIG. 10). Therefore, the value of the reference current Iref_BA1 at the node N30 is set to I3+Ibase. Similarly, the value of the reference current Iref_BA2 at the node N40 is set to I2+I3+Ibase and the value of the reference current Iref_BA3 at the node N50 is set to I1+I2+I3+Ibase.

As described above, the farther it is from the selected block BLK area, the smaller the value of the reference current applied to the sense amplifier SA is made. Meanwhile, the signals Blk area0 to Blk area3 are controlled to any signal of the “L” level and the “H” level by the controller 40 according to the selected block BLK.

The semiconductor storage device according to this embodiment may prevent the erroneous reading of the data by making the value of the reference current Iref applied to the sense amplifier SA variable. That is to say, the semiconductor storage device according to this embodiment is provided with the controller, which makes the value of the reference current Iref applied to each sense amplifier SA variable according to the block BLK, which is made the read target. By the controller, it is possible to decrease an effect of the parasitic resistance due to the wiring length of the global signal line changed according to the arranging positions of the block BLK, which is made the read target, and of the sense amplifier SA. That is to say, as described above, when the block BLK, which is made the reading target, is located on a position far from the sense amplifier SA, the current value sensed by the sense amplifier SA is subject to the effect of the parasitic resistance of the global signal line through which the current passes in addition to the current value due to the data held by the memory cell MC. Therefore, it is required to sense while considering the parasitic resistance of the global signal line. In view of such a problem, the semiconductor storage device according to this embodiment increases or decreases the value of the reference current Iref, which is a criterion, when sensing the current decreased by the parasitic resistance. Specifically, when the position of the block BLK in the selected state is distant from the sense amplifier SA, the distance of the global signal line through which the current to be sensed passes becomes longer. That is to say, the parasitic resistance increases. Therefore, even when the data held by the memory cell MC is the “1” data (refer to FIG. 6), a current Icell_on₁ (<current Icel_on) lower than the original current Icell_on might be sensed. In this case, the above-described Icell_on₁ is sensed by decreasing from the initial value of the reference current Iref as illustrated in FIGS. 10 and 11. According to this, it is possible to correctly read the data regardless of the parasitic resistance due to the wiring length of the global signal line.

On the other hand, when the position of the block BLK in the selected state is closer to the sense amplifier SA (for example, a status in which the block BLK located just above the sense amplifier SA is selected), the distance of the global signal line through which the current to be sensed passes becomes shorter than that in the above-described case. That is to say, the effect of the parasitic resistance by the global signal line becomes smaller. Therefore, the sense amplifier SA may sense the current according to the data held by the memory cell MC.

As described above, the controller 40 manages the positions of the block BLK in the selected state and each sense amplifier SA and controls the value of the reference current Iref applied to the sense amplifier SA, thereby preventing the erroneous reading of the data.

Meanwhile, although the blocks BLK0 to BLK31 are divided into four in the above-described embodiment, the similar effect may also be obtained when they are divided in two. That is to say, the blocks BLK0 to BLK15 are made the 0th block BLK area and the remaining blocks BLK are made the 1st block BLK area. Further, the configuration may be that required for generating an appropriate reference current Iref also in the reference current generating circuits 20-0 to 20-3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor storage device comprising:
a plurality of blocks which includes memory cells arranged in a row direction and in a column direction, the memory cells each holding data;
a stripe including the blocks, the blocks being arranged in a first direction to form the stripe;
sense amplifiers which read the data, the sense amplifiers being provided on a silicon substrate, each of the blocks being located above a corresponding one of the sense amplifiers;
a global signal line formed so as to penetrate through the stripe in the first direction, which transfers the data read from one of the blocks to at least one of the sense amplifiers; and
a controller, which controls a value of a reference current applied to the sense amplifiers according to positional relationship between each area in which the sense amplifiers are arranged and ones of the blocks, each of which is determined as a read target of the data.

2. The device according to claim 1, wherein
the memory cells each include a variable resistive element and a rectifying device, and
the controller controls the value of the reference current according to a wiring length of the global signal line corresponding to a distance from the one of the blocks, which is determined as the read target, to the at least one of the sense amplifiers, which reads the data.

3. The device according to claim 2, wherein
the controller decreases the value as the wiring length becomes longer.

4. The device according to claim 2, wherein
a first block group and a second block group are formed as aggregations in which the blocks are aggregated according to an arrangement position in the stripe, each of the sense amplifiers is arranged just under a corresponding one of the first block group and the second block group, and
the controller supplies a first current or a second current larger than the first current as the reference current to the sense amplifiers according to a signal indicating whether the one of the blocks, which is determined as the read target, is in the first block group or the second block group.

5. The device according to claim 4, wherein
when the signal indicates the first block group, the first current flows to the sense amplifiers that are arranged just under the first block group and the second current flows to the sense amplifiers that are arranged just under the second block group.

6. The device according to claim 5, wherein
the controller includes a logic circuit, which performs operation of the signal.

7. The device according to claim 1, wherein
the controller controls the reference current according to difference in a wiring resistance value of the global signal line.

8. The device according to claim 1, wherein
a bit line and a word line, which select one of the memory cells, are formed in each of the blocks,
a first signal line, which connects the bit line and the global signal line, is formed in each of the blocks and has a same length in each of the blocks, and
a second signal line, which connects the global signal line and each of the sense amplifiers, has a same length for each of the sense amplifiers.

9. The device according to claim 7, wherein
the controller uses a first current as the reference current applied to the sense amplifiers when a value of the wiring resistance value is small, and uses a second current smaller than the first current as the reference current applied to the sense amplifiers when the value of the wiring resistance value is large.

10. A semiconductor storage device comprising:
a first block comprising a first memory cell array including a first memory cell provided at an intersection of a bit line and a word line, the first memory cell including a first variable resistive element and a first diode and holding first data corresponding to a resistance value of the first variable resistive element;
a second block comprising a second memory cell array including a second memory cell provided at an intersection of another bit line and another word line, the second memory cell including a second variable resistive element and a second diode and holding second data corresponding to a resistance value of the second variable resistive element;
a selecting circuit, which selects either the first block or the second block;
a global signal line connected to any of the first block and the second block selected by the selecting circuit;
sense amplifiers which sense a current flowing to the global signal line; and
a controller, which detects a read address and grasps a wiring length of the global signal line required for a data read operation, to read either the first data or the second data, from a block corresponding to the read address to be sensed by at least one of the sense amplifiers.

11. (canceled)

12. (canceled)

13. The device according to claim 11, wherein
the controller uses a first current as the reference current when the wiring length is short, and uses a second current smaller than the first current as the reference current when the wiring length is long.

14. (canceled)

15. The device according to claim 10, further comprising:
a second global signal line arranged so as to be adjacent to the global signal line,
wherein the selecting circuit includes:
a first selecting circuit, which transfers the first data from the first memory cell to the global signal line; and
a second selecting circuit, which transfers the second data from the second memory cell to the second global signal line;
wherein the first selecting circuit and the second selecting circuit are alternately arranged.

16. The device according to claim 11, wherein
the controller includes:
a plurality of switch circuits connected in common at a first node at which a desired reference current is supplied, which controls an amount of the reference current; and
a logical operation circuit, which controls on/off of each of the switch circuits.

17. The device according to claim 10, further comprising:
an aggregation in which n blocks, including the first block and the second block, are formed in a first direction,
wherein the controller divides the n blocks formed in the aggregation into two groups according to a position at which each of the n blocks is formed and controls a value of a reference current to be supplied to the at least one of the sense amplifiers, which is provided so as to correspond to the block corresponding to the read address from which the first data or the second data is to be read.

18. The device according to claim 17, wherein
the controller controls the reference current applied to the at least one of the sense amplifiers according to the wiring length.

19. The device according to claim 17, wherein
the controller controls the reference current applied to the at least one of the sense amplifiers according to a wiring resistance corresponding to the wiring length.

20. The device according to claim 18, wherein
the controller uses a first current as the reference current when the wiring length is short, and uses a second current smaller than the first current as the reference current when the wiring length is long.

21. The device according to claim 10, wherein
the sense amplifiers are provided on a silicon substrate, and each of the first block and the second block is located above a corresponding one of the sense amplifiers.

22. The device according to claim 10, wherein
the selecting circuit includes a driver serving as a first selector and a multiplexer serving as a second selector,
the driver selects one of the bit line and the other bit line and one of the word line and the other word line, and
the multiplexer selects any of the first block and the second block.

23. The device according to claim 1, wherein
the blocks include a first block, a second block, and a third block that are adjacent to each other,
the second block is connected to the first block commonly by a first word line group,
the second block is connected to the third block commonly by a second word line group different from the first word line group.

24. The device according to claim 1, wherein
the blocks include a first block, a second block, a third block, and a fourth block that are adjacent to each other,
the first block is connected to the second block commonly by a first word line group,
the third block is connected to the fourth block commonly by a second word line group different from the first word line group,
the first block disconnects the third and fourth block.

25. The device according to claim 10, further comprising:
a third block; and
a fourth block, wherein
the third block and the fourth block are adjacent to the first block,
the first block is connected to the third block commonly by a first word line group, and
the first block is connected to the fourth block commonly by a second word line group different from the first word line group.
